(19) United States
(12) Patent Application Publication
(10) Pub. No.: US 2025/0176396 A1
(43) Pub. Date: May 29, 2025

(54) DISPLAY DEVICE AND METHOD OF MANUFACTURING THEREOF

(71) Applicant: Samsung Display Co., LTD., Yongin-si (KR)

(72) Inventors: Sun Kyu JOO, Yongin-si (KR); Jae Cheol PARK, Yongin-si (KR); Cheol SHIN, Yongin-si (KR); Keun Chan OH, Yongin-si (KR); Do Kyung YOUN, Yongin-si (KR); Ji Hwan YOON, Yongin-si (KR); Woo Man JI, Yongin-si (KR); You Young JIN, Yongin-si (KR); Tae Hyung HWANG, Yongin-si (KR)

(21) Appl. No.: 18/784,786

(22) Filed: Jul. 25, 2024

(30) Foreign Application Priority Data
Nov. 29, 2023 (KR) 10-2023-0169766

(51) Int. Cl. H10K 59/38; H10K 59/12; H10K 59/122; H10K 59/80

(52) U.S. Cl. CPC H10K 59/38; H10K 59/1201; H10K 59/122; H10K 59/8792

(57) ABSTRACT

A display device includes a substrate including light-transmitting areas and light-blocking areas, a color filter layer including color filters above the light-transmitting areas, first patterns below the color filter layer, and overlapping the light-transmitting areas, and second patterns below the color filter layer, and overlapping the light-blocking area.

### CROSS-REFERENCE TO RELATED APPLICATION

The present application claims priority to, and the benefit of, Korean Patent Application No. 10-2023-0169766, filed on Nov. 29, 2023, in the Korean Intellectual Property Office, the entire disclosure of which is incorporated herein by reference.

### BACKGROUND

### 1. Field

Aspects of embodiments of the present disclosure relate to a display device, and to a method of manufacturing the display device.

### 2. Description of the Related Art

As information technology has developed, importance of a display device, which is a connection medium between a user and information, has been highlighted. Accordingly, the use of display devices, such as a liquid crystal display device, an organic light-emitting display device, and the like has been increasing.

### SUMMARY

Embodiments of the present disclosure provide a display device, and a method of manufacturing the display device, the display device being readily manufactured and capable of reducing manufacturing costs.

The aspects of the disclosure are not limited to those described herein, and other aspects that are not mentioned herein would be clearly understood by a person skilled in the art from the description of the disclosure.

According to embodiments of the present disclosure, a display device includes a substrate including light-transmitting areas and light-blocking areas, a color filter layer including color filters above the light-transmitting areas, first patterns below the color filter layer, and overlapping the light-transmitting areas, and second patterns below the color filter layer, and overlapping the light-blocking area.

The first patterns and the second patterns may be at a same layer.

The first patterns and the second patterns may include a same material.

The first patterns and the second patterns may include scatterers.

The display device may further include a bank defining first openings surrounding the first patterns, and respectively exposing portions of the first patterns.

The bank may further define second openings surrounding the second patterns, and respectively exposing portions of the second patterns.

The display device may further include a spacer overlapping one of the second patterns.

The spacer and the bank may include a same material.

The spacer and the bank may include a light-blocking material or a black material.

The spacer and the bank may include a non-liquid repellent material.

The display device may further include a low refractive index layer overlapping the color filter layer, and a capping layer overlapping the low refractive index layer.

The display device may further include a display substrate including light-emitting structures, wherein no light conversion layer exists between the color filter layer and the light-emitting structures.

According to embodiments of the present disclosure, a method of manufacturing a display device includes providing a substrate including light-transmitting areas and light-blocking areas, forming a color filter layer including color filters on the light-transmitting areas, forming first patterns overlapping the light-transmitting areas, and forming second patterns overlapping the light-blocking area on the color filter layer.

The first patterns and the second patterns may be formed in one process.

The first patterns and the second patterns may be made of a same material.

The first patterns and the second patterns may include scatterers.

The method may further include forming a bank on the first patterns and the second patterns, and forming a spacer on one of the second patterns.

The bank and the spacer may be formed in one process.

The bank may define first openings surrounding the first patterns, and respectively exposing portions of the first patterns, and defines second openings surrounding the second patterns, and respectively exposing portions of the second patterns.

The spacer and the bank may include a same material.

The spacer and the bank may include a light-blocking material or a black material.

The spacer and the bank may include a non-liquid repellent material.

The method may further include forming a low refractive index layer overlapping the color filter layer, and forming a capping layer overlapping the low refractive index layer.

### BRIEF DESCRIPTION OF THE DRAWINGS

The above and other aspects of the present disclosure will become more apparent by describing, in further detail, embodiments thereof with reference to the accompanying drawings, in which:

FIG. 1 is a perspective view of a display device in accordance with one or more embodiments.

FIG. 2 is a cross-sectional view taken along the line I-I′ of FIG. 1.

FIG. 3 is a schematic layout of a pixel arrangement of a display device in accordance with one or more embodiments.

FIG. 4 is a cross-sectional view of a display device in accordance with one or more embodiments.

FIG. 5 is a cross-sectional view of a display device in accordance with one or more embodiments.

FIG. 6 is a flowchart of a method of manufacturing a display device in accordance with one or more embodiments.

FIGS. 7 to 14 are cross-sectional views of process operations of a method of manufacturing a display device in accordance with one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

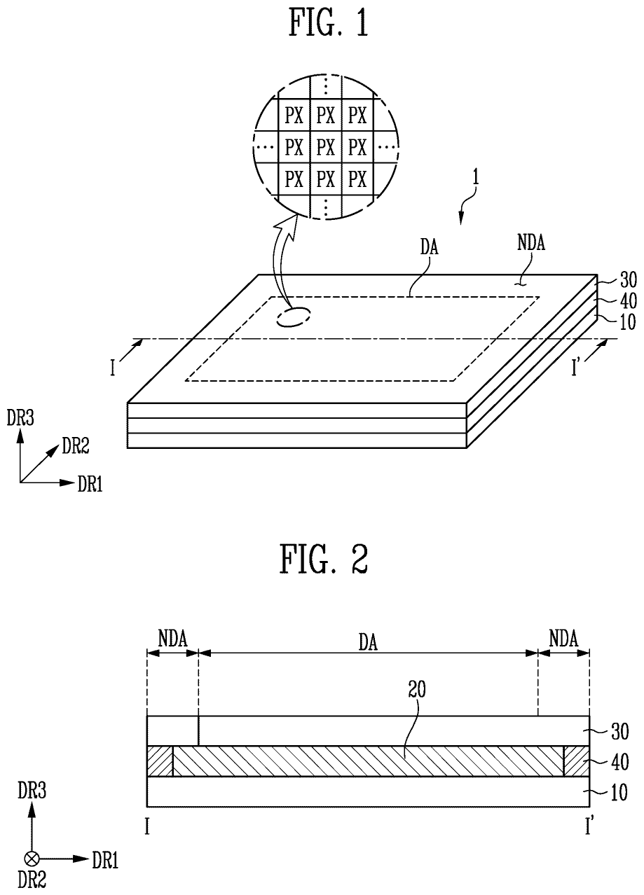

FIG. 1 is a perspective view of a display device in accordance with one or more embodiments. FIG. 2 is a cross-sectional view taken along the line I-I′ of FIG. 1.

Referring to FIG. 1 and FIG. 2, a display device 1 may refer to any electronic device that provides a display screen. For example, televisions, televisions, laptops, monitors, billboards, mobile phones, smart phones, tablet personal computers (PC), electronic watches, smartwatches, watch phones, mobile communication terminals, electronic notebooks, electronic books, portable multimedia players (PMP), navigations, game consoles, digital cameras, internet of things that provide a display screen may be included in the display device 1.

A first direction DR1 and a second direction DR2 may be directions perpendicular to each other within one plane. A third direction DR3 may be a direction perpendicular to the plane in which the first direction DR1 and the second direction DR2 are located. The third direction DR3 may be perpendicular to the first direction DR1 and the second direction DR2, respectively. In embodiments, the third direction DR3 represents a thickness direction of the display device 1.

The display device 1 may have a rectangular shape in a plan view. For example, the display device 1 may have a rectangular planar shape with long sides in the first direction DR1, and short sides in the second direction DR2. A corner where the long side in the first direction DR1 and the short side in the second direction DR2 of the display device 1 meet may be formed at a right angle or rounded to have a curvature (e.g., predetermined curvature). The planar shape of the display device 1 is not limited to the example, and may be applied as a circular shape or other shape.

The display device 1 may include a display area DA that displays an image and a non-display area NDA that does not display an image. The display area DA may include pixels PX. The non-display area NDA may be around the display area DA, and may surround the display area DA (e.g., in plan view).

The display device 1 may include a display substrate 10, and a color filter substrate 30 that faces the display substrate 10. The display device 1 may further include a filling layer 20 filled between the display substrate 10 and the color filter substrate 30, and a sealing member 40 that couples the display substrate 10 and the color filter substrate 30.

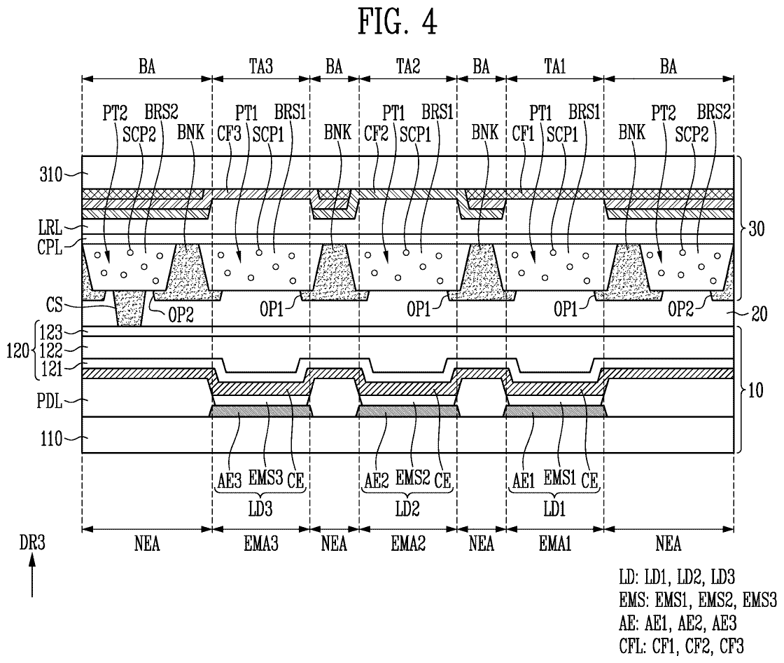

The display substrate 10 may emit light having a peak wavelength (e.g., predetermined peak wavelength) from the light-emitting areas of the display area DA. The display substrate 10 may include elements and circuits for displaying an image. For example, the display substrate 10 may include a pixel circuit, such as a switching element, a pixel-defining film PDL (see FIG. 4) that defines the light-emitting areas and non-light-emitting areas of the display area DA, and a self-light-emitting element. The self-light-emitting element may include at least one of an organic light-emitting diode, a quantum dot light-emitting diode, an inorganic-based micro-light-emitting diode (for example, micro LED), or an inorganic-based nano-light-emitting element (for example, nano LED), but embodiments are not limited thereto.

The color filter substrate 30 may be located on an upper portion of the display substrate 10, and may face the display substrate 10. The color filter substrate 30 may maintain and transmit a peak wavelength of light emitted from the display substrate 10, but embodiments are not limited thereto. For example, the color filter substrate 30 may convert and transmit a peak wavelength of light emitted from the display substrate 10.

The sealing member 40 may be located between the display substrate 10 and the color filter substrate 30 in the non-display area NDA. The sealing member 40 is located along the edges of the display substrate 10 and the color filter substrate 30 in the non-display area NDA, and may surround the display area DA in a cross-sectional view. The display substrate 10 and the color filter substrate 30 may be bonded to each other through the sealing member 40.

The filling layer 20 may be located in the space between the display substrate 10 and the color filter substrate 30 surrounded by the sealing member 40. The filling layer 20 may fill a space between the display substrate 10 and the color filter substrate 30. The filling layer 20 may be made of a material that may transmit light. The filling layer 20 may include an organic material. For example, the filling layer 20 may be made of a silicon-based organic material, and an epoxy-based organic material, or the like, but embodiments are not limited thereto.

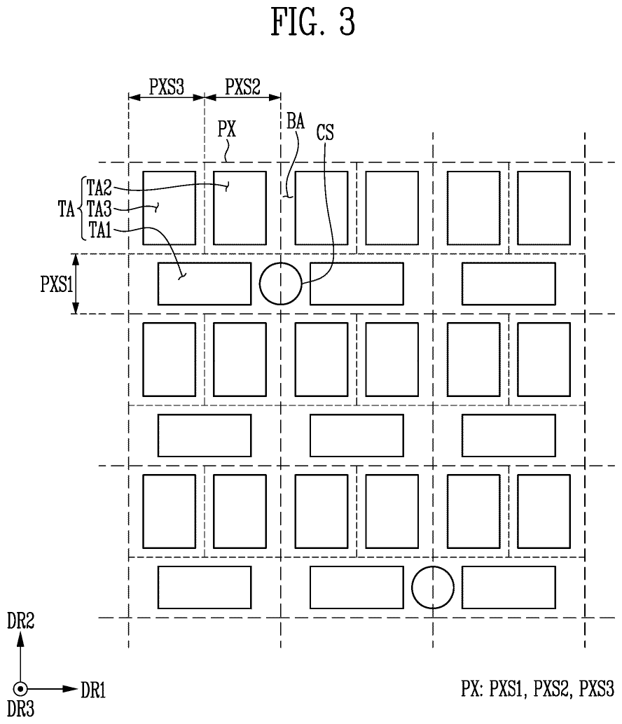

FIG. 3 is a schematic layout of a pixel arrangement of a display device in accordance with one or more embodiments.

Referring to FIG. 1 and FIG. 3, the display area DA of display device 1 includes the pixels PX. Each of the pixels PX means a minimum unit that is repeated for display. In order to display a full color, each of the pixels PX may include first to third sub-pixels PXS1, PXS2, and PXS3 emitting different respective colors. For example, each of the pixels PX may include a first sub-pixel PXS1 emitting light of a first color, a second sub-pixel PXS2 emitting light of a second color, and a third sub-pixel PXS3 emitting light of a third color. The first color may be blue, the second color may be green, and the third color may be red, but embodiments are not limited thereto. The first sub-pixel PXS1, the second sub-pixel PXS2, and the third sub-pixel PXS3 may be provided one by one for each of the pixels PX, but embodiments are not limited thereto.

Each of the pixels PX may include light-transmitting areas TA, and a light-blocking area BA around the light-transmitting areas TA. The light-transmitting areas TA may be areas in which light emitted from the display substrate 10 transmits through the color filter substrate 30 to be emitted to the outside of the display device 1. The light-blocking area BA may be an area in which light emitted from the display substrate 10 is not transmitted.

Each of the light-transmitting areas TA may include a first light-transmitting area TA1, a second light-transmitting area TA2, and a third light-transmitting area TA3. Each of the first to third light-transmitting areas TA1, TA2, and TA3 may be a light-transmitting area of each of the first to third sub-pixels PXS1, PXS2, and PXS3. For example, the first light-transmitting area TA1 may be the light-transmitting area of the first sub-pixel PXS1, the second light-transmitting area TA2 may be the light-emitting area of the second sub-pixel PXS2, and the third light-transmitting area TA3 may be the light-transmitting area of the third sub-pixel PXS3.

The first to third light-transmitting areas TA1, TA2, and TA3 may be located in an S-stripe type in each of the pixels PX. For example, the second light-transmitting area TA2 and the third light-transmitting area TA3 may be located in odd rows, and may be continuously and alternately located in the row direction. The first light-transmitting area TA1 may be located in even rows, and may be continuously and alternately located in the row direction.

The shapes of the first to third sub-pixels PXS1, PXS2, and PXS3 may have a similar shape relationship with respect to the shape of the light-transmitting area of the corresponding pixel, but embodiments are not limited to this. The shape and arrangement of the first to third light-transmitting areas TA1, TA2, and TA3 are not limited to the one or more embodiments corresponding to FIG. 3, and may be variously modified.

The light-blocking area BA may surround the light-transmitting areas TA. For example, the first to third light-transmitting areas TA1, TA2, and TA3 may be divided or defined by the light-blocking area BA. The light-blocking area BA of each of the pixels PX directly contacts the light-blocking area BA of a neighboring pixel. For example, the light-blocking areas BA of neighboring pixels may be connected as one. Furthermore, the light-blocking areas BA of all pixels PX may be connected as one, but embodiments are not limited thereto.

In one or more embodiments, the display device 1 may include at least one spacer CS. The spacer CS may be located in the light-blocking area BA. For example, the spacer CS may overlap the light-blocking area BA, and may not overlap the light-transmitting areas TA. The spacer CS may be located between one or more adjacent ones of the pixels PX, but embodiments are not limited thereto. For example, in one or more other embodiments, one spacer CS or a plurality of spacers CS may be located for each of the pixels PX. That is, the number and disposition of the spacers CS may be changed according to the resolution, product specifications, and the like of the display device 1.

The spacer CS may serve to maintain a gap between the display substrate 10 and the color filter substrate 30.

The pixels PX may be alternately arranged in a matrix direction, respectively, but embodiments are not limited thereto. The shapes and arrangements of the first to third sub-pixels PXS1, PXS2, and PXS3 included in each of the pixels PX may be the same, but embodiments are not limited thereto. The shape of each of the pixels PX may be a substantially square shape, but embodiments are not limited thereto. For example, the shape of each of the pixels PX may be variously modified, such as a rhombus shape and a rectangular shape.

FIG. 4 is a cross-sectional view of a display device in accordance with one or more embodiments.

Referring to FIG. 4, the display substrate 10 may include a first substrate 110, a pixel-defining film PDL, light-emitting elements LD, and an encapsulation layer 120 covering the light-emitting elements LD located on one surface of the first substrate 110. The color filter substrate 30 may include a second substrate 310 facing the first substrate 110, and a low reflection layer LRL, a capping layer CPL, first patterns PT1, second patterns PT2, a bank BNK, and a spacer CS located on (e.g., below) one surface of the second substrate 310.

Hereinafter, the display substrate 10 will be described in more detail.

The first substrate 110 may be an insulating substrate. The first substrate 110 may include a transparent material. For example, the first substrate 110 may include a transparent insulating material, such as glass, quartz, and the like, but embodiments are not limited thereto. The first substrate 110 may be a rigid substrate, but embodiments are not limited thereto. For example, the first substrate 110 may include plastic, such as polyimide, and may have flexible characteristics that may be curved, bent, folded, or rolled.

Anode electrodes AE may be located on one surface of the first substrate 110. For example, the first to third anode electrodes AE1, AE2, and AE3 may be arranged on one surface of the first substrate 110 to be separated from each other. A circuit layer for driving the first to third light-emitting elements LD1, LD2, and LD3, respectively, may be located between the first substrate 110 and the first to third anode electrodes AE1, AE2, and AE3. The circuit layer may include thin film transistors, capacitors, and the like.

The anode electrodes AE may have a structure in which a material layer having a high work function, such as an indium tin oxide (ITO), an indium zinc oxide (IZO), a zinc oxide (ZnO), and an indium oxide (In₂O₃), and a reflective material layer, such as silver (Ag), magnesium (Mg), aluminum (AI), platinum (Pt), lead (Pd), gold (Au), nickel (Ni), neodymium (Nd), iridium (Ir), chromium (Cr), lithium (Li), calcium (Ca), or a mixture thereof are stacked. The material layer having the high work function may be located above the reflective material layer to be located close to the first to third light-emitting layers EML1, EML2, and EML3. For example, the anode electrodes AE may have a multi-layered structure, such as ITO/Mg, ITO/Ag, and ITO/Ag/ITO, but embodiments are not limited thereto.

The pixel-defining film PDL may be located on one surface of the first substrate 110. The pixel-defining film PDL is located on the anode electrodes AE, and may include openings that expose the anode electrodes AE. A non-light-emitting area NEA and first to third light-emitting areas EMA1, EMA2, and EMA3 may be distinguished by the pixel-defining film PDL and the openings thereof. The pixel-defining film PDL may separate and insulate the anode electrodes AE from each other.

The pixel-defining film PDL may include an organic insulating material, such as an acrylic resin, an epoxy resin, a phenolic resin, a polyamide resin, a polyimide resin, an unsaturated polyesters resin, a polyphenylenethers resin, a polyphenylenesulfides resin, or a benzocyclobutene, but embodiments are not limited thereto. For example, the pixel-defining film PDL may include an inorganic material.

Light emitting structures EMS may be located on the anode electrodes AE exposed by the pixel-defining film PDL. The light-emitting structures EMS may include a first light-emitting structure EMS1, a second light-emitting structure EMS2, and a third light-emitting structure EMS3. For example, the first light-emitting structure EMS1 may be located on the first anode electrode AE1, the second light-emitting structure EMS2 may be located on the second anode electrode AE2, and the third light-emitting structure EMS3 may be located on the third anode electrode AE3.

In one or more embodiments, the light-emitting structures EMS may include light-emitting layers. For example, the light-emitting structures EMS may include a first light-emitting layer that emits light in a first color (for example, blue) wavelength band, a second light-emitting layer that emits light in a second color (for example, green) wavelength band, and a third light-emitting layer that emits light in a third color (for example, red). However, the embodiments are not limited thereto, and the wavelength band of the light emitted by the light-emitting layers and the number of the light-emitting layers may be changed. The light-emitting layers may be configured of an organic light-emitting layer including an organic material and/or an inorganic light-emitting layer including an inorganic material. In some embodiments, the light-emitting structures EMS may further include a hole injection layer, a hole transport layer, an electron injection layer, and an electron transport layer as an auxiliary layer that assists light emission.

In one or more embodiments, the light-emitting structures EMS may have a tandem structure including light-emitting layers overlapping each other in the thickness direction, and a charge generation layer located therebetween. The light-emitting layers overlapping each other may emit light of different wavelengths, but embodiments are not limited thereto. For example, the light-emitting layers overlapping each other may emit light of the same wavelength.

In one or more embodiments, the color of light emitted by each of the light-emitting structures EMS may be the same for each of the light-emitting elements LD. For example, the first light-emitting structure EMS1 of the first light-emitting element LD1, the second light-emitting structure EMS2 of the second light-emitting element LD2, and the third light-emitting structure EMS3 of the third light-emitting element LD3 may emit light of a color (for example, white) mixed with the first color (for example, blue), the second color (for example, green), and the third color (for example, red). That is, the light-emitting structures EMS may emit light of the same color. In this case, light of the same color emitted from the light-emitting structures EMS may be separated into light of a desired color through a color filter layer CFL to be described later.

A cathode electrode CE may be located on the light-emitting structures EMS. For example, the cathode electrode CE may be located on the first to third light-emitting structures EMS1, EMS2, and EMS3. The cathode electrode CE may not only be in contact with the first to third light-emitting structures EMS1, EMS2, and EMS3, but may also be in contact with the upper surface of the pixel-defining film PDL. The cathode electrode CE may be connected to the first to third sub-pixels PXS1, PXS2, and PXS3 (see FIG. 3) without distinction. For example, the cathode electrode CE may be a front electrode located entirely without distinction between the first to third sub-pixels PXS1, PXS2, and PXS3.

The cathode electrode CE may include a material layer having a small work function, such as Li, Ca, LiF/Ca, LiF/Al, Al, Mg, Ag, Pt, Pd, Ni, Au Nd, Ir, Cr, BaF, Ba, or a compound or mixture thereof, but embodiments are not limited thereto. For example, the cathode electrode CE may further include a transparent metal oxide layer located on the material layer having the small work function.

The anode electrodes AE, the light-emitting structures EMS, and the cathode electrode CE may configure the light-emitting elements LD. For example, the first anode electrode AE1, the first light-emitting structure EMS1, and the cathode electrode CE may configure the first light-emitting element LD1, the second anode electrode AE2, the second light-emitting structure EMS2, and the cathode electrode CE may configure the second light-emitting element LD2, and the third anode electrode AE3, the third light-emitting structure EMS3, and the cathode electrode CE may configure the third light-emitting element LD3. Light emitted from the light-emitting elements LD may be emitted in the display direction, for example, in the third direction DR3 through the cathode electrode CE.

The encapsulation layer 120 may be located on the upper portion of the cathode electrode CE. The encapsulation layer 120 may include at least one thin film. For example, the encapsulation layer 120 may include a first inorganic layer 121, an organic layer 122, and a second inorganic layer 123. Each of the first inorganic layer 121 and the second inorganic layer 123 may include a silicon nitride, a silicon oxide, silicon oxynitride, or the like. The organic layer 122 may include an organic insulating material, such as an acrylic resin, an epoxy resin, a phenolic resin, a polyamide resin, a polyimide resin, an unsaturated polyesters resin, a polyphenylenethers resin, a polyphenylenesulfides resin, or a benzocyclobutene.

Hereinafter, the color filter substrate 30 will be described in more detail.

The color filter substrate 30 may face the display substrate 10 on the upper portion of the encapsulation layer 120. When the cross-sectional structure of the color filter substrate 30 is sequentially described in the opposite direction of the third direction DR3, that is, the lower/downward direction, the second substrate 310 of the color filter substrate 30 may include a transparent material. For example, the second substrate 310 may include a transparent insulating material, such as glass, quartz, and the like, but embodiments are not limited thereto. The second substrate 310 may be a rigid substrate, but embodiments are not limited thereto. For example, the second substrate 310 may include plastic, such as polyimide, and may have flexible characteristics that may be curved, bent, folded, or rolled.

The second substrate 310 may be the same substrate as the first substrate 110, or may be a substrate different from the first substrate 110 in material, thickness, transmittance, and the like. For example, the second substrate 310 may have a transmittance that is higher than that of the first substrate 110. Because the second substrate 310 includes a light-transmitting material, light emitted from the first to third light-transmitting areas TA1, TA2, and TA3 may be provided to the outside.

A color filter layer CFL may be located on one surface of the second substrate 310. For example, the color filter layer CFL may be located throughout the first to third light-transmitting areas TA1, TA2, and TA3 and the light-blocking area BA. The color filter layer CFL may block light of a color other than a desired color from being emitted from light emitted from each of the light-emitting elements LD.

The color filter layer CFL may include first to third color filters CF1, CF2, and CF3. Each of the first to third color filters CF1, CF2, and CF3 may transmit light of a corresponding color, and may block or absorb light of a color(s) different from the corresponding color.

The first color filter CF1 may selectively transmit the light of the first color (for example, blue light), and may block or absorb the light of the second color (for example, green light) and the light of the third color (for example, red light), which are different from the first color. Accordingly, the light of the first color may be emitted from the first sub-pixel PXS1 (see FIG. 3). The first color filter CF1 may include a blue colorant, such as a blue dye or a blue pigment. The first color filter CF1 may be located on one surface of the second substrate 310 in the first light-transmitting area TA1. The first color filter CF1 may also be partially located on one surface of the second substrate 310 in the light-blocking area BA.

The second color filter CF2 may selectively transmit the light of the second color (for example, green light), and may block or absorb the light of the first color (for example, blue light) and the light of the third color (for example, red light), which are different from the second color. Accordingly, the light of the second color may be emitted from the second sub-pixel PXS2 (see FIG. 3). The second color filter CF2 may include a green colorant, such as a green dye or a green pigment. The second color filter CF2 may be located on one surface of the second substrate 310 in the second light-transmitting area TA2. The second color filter CF2 may be partially located on one surface of the second substrate 310 in the light-blocking area BA and on the first color filter CF1.

The third color filter CF3 may selectively transmit the light of the third color (for example, red light), and may block or absorb the light of the first color (for example, blue light) and the light of the second color (for example, green light), which are different from the third color. Accordingly, the light of the third color may be emitted from the third sub-pixel PXS3 (see FIG. 3). The third color filter CF3 may include a red colorant, such as a red dye or a red pigment. The third color filter CF3 may be located on one surface of the second substrate 310 in the third light-transmitting area TA3. The third color filter CF3 may be partially located on one surface of the second substrate 310 in the light-blocking area BA, and between the first color filter CF1 and the second color filter CF2.

A low refractive index layer LRL may be located on the color filter layer CFL. The low refractive index layer LRL may have a refractive index that is less than that of the first and second patterns PT1 and PT2. The low refractive index layer LRL may include an organic film with a relatively low refractive index. The low refractive index layer LR may further include or define hollow particles and/or voids dispersed in the organic film, and the refractive index of the low refractive index layer LRL may be adjusted by the ratio of the hollow particles and/or the voids.

The capping layer CPL may be located on the low refractive index layer LRL. The capping layer CPL may reduce or prevent impurities, such as moisture or air, from penetrating from the outside to damage or contaminate the color filter layer CFL. In addition, the capping layer CPL may reduce or prevent the likelihood of a colorant of the color filter layer CFL being diffused into other components. The capping layer CPL may include an inorganic material. For example, the capping layer CPL may include a silicon nitride, an aluminum nitride, a zirconium nitride, a titanium nitride, a hafnium nitride, a tantalum nitride, a silicon oxide, an aluminum oxide, a titanium oxide, a tin oxide, a silicon oxynitride, or a combination thereof.

The first patterns PT1 may be located on (e.g., below) the capping layer CPL. For example, some of the first patterns PT1 may be located on (e.g., below) the capping layer CPL on the first color filter CF1 in the first transmitting area TA1. For example, some of the first patterns PT1 may be located on (e.g., below) the capping layer CPL on the second color filter CF2 in the second transmitting area TA2. For example, some of the first patterns PT1 may be located on (e.g., below) the capping layer CPL on the third color filter CF3 in the third transmitting area TA3. Some of the first patterns PT1 may also be located on (e.g., below) the capping layer CPL in the light-blocking area BA. The first patterns PT1 may be spaced apart from each other on (e.g., below) the capping layer CPL.

Each of the first patterns PT1 may include a first base resin BRS1 and first scatterers SCP1 dispersed within the first base resin BRS1. In one or more embodiments, each of the first patterns PT1 may omit a wavelength conversion material (for example, quantum dot). Because the first to third light-emitting elements LD1, LD2, and LD3 emit light of a color (for example, white) mixed with the first color (for example, blue), the second color (for example, green), and the third color (for example, red) rather than a single color, various colors may be implemented without a wavelength conversion material.

The first base resin BRS1 may include a material with relatively high light transmittance. The first base resin BRS1 may be made of a transparent organic material. For example, the first base resin BRS1 may include at least one organic material, such as an epoxy resin, an acrylic resin, a cardo resin, or an imide resin.

The first scatterers SCP1 may have a different refractive index from the first base resin BRS1, and may form an optical interface with the first base resin BRS1. The first scatterers SCP1 may include light-scattering particles that scatter at least a portion of the transmitted light. For example, the first scatterers SCP1 may include a metal oxide, such as a titanium oxide (TiO2), a zirconium oxide (ZrO2), an aluminum oxide (Al₂O₃), an indium oxide (In₂O₃), a zinc oxide (ZnO), or a tin oxide (SnO2), or may include an organic particle, such as an acrylic resin or a urethane resin. The first scatterers SCP1 may scatter light in a random direction regardless of an incident direction of incident light, without substantially converting a peak wavelength of the incident light.

Some of the first patterns PT1 may overlap the first color filter CF1 located in the first light-transmitting area TA1 in the third direction DR3. Some of the first patterns PT1 may maintain and transmit the wavelength of light emitted from the display substrate 10 to be incident on some of the first patterns PT1. For example, light of the first color (for example, blue light) emitted from the first light-emitting area EMA1 may transmit through some of the first patterns PT1 and the first color filter CF1 to be emitted to the outside.

Some of the first patterns PT1 may overlap the second color filter CF2 located in the second light-transmitting area TA2 in the third direction DR3. Some of the first patterns PT1 may maintain and transmit the wavelength of light emitted from the display substrate 10 to be incident on some of the first patterns PT1. For example, light of the second color (for example, green light) emitted from the second light-emitting area EMA2 may transmit through some of the first patterns PT1 and the second color filter CF2 to be emitted to the outside.

Some of the first patterns PT1 may overlap the third color filter CF3 located in the third light-transmitting area TA3 in the third direction DR3. Some of the first patterns PT1 may maintain and transmit the wavelength of light emitted from the display substrate 10 to be incident on some of the first patterns PT1. For example, light of the third color (for example, red light) emitted from the third light-emitting area EMA3 may transmit through some of the first patterns PT1 and the third color filter CF3 to be emitted to the outside.

The second patterns PT2 may be located on (e.g., below) the capping layer CPL. For example, the second patterns PT2 may be located on (e.g., below) the capping layer CPL in the light-blocking area BA. The second patterns PT2 may be spaced apart from each other on (e.g., below) the capping layer CPL. The second patterns PT2 may be spaced apart from the first patterns PT1 on (e.g., below) the capping layer CPL. The second patterns PT2 may be formed in a single process together with the first patterns PT1. For example, the first patterns PT1 and the second patterns PT2 may be concurrently or substantially simultaneously patterned through exposure and development after applying a photosensitive material. The second patterns PT2 may be located on the same layer as first patterns PT1.

Each of the second patterns PT2 may include a second base resin BRS2, and second scatterers SCP2 dispersed within the second base resin BRS2. In one or more embodiments, each of the second patterns PT2 may omit a wavelength conversion material (for example, quantum dot). The second base resin BRS2 may include substantially the same material as the first base resin BRS1. The second scatterers SCP2 may include substantially the same material as the first scatterers SCP1. The second scatterers SCP2 may perform the same function as the first scatterers SCP1, but may overlap the non-light-emitting area NEA to substantially have no incident light.

The second patterns PT2 may provide a surface step to the light-blocking area BA, thereby contributing to the formation of the bank BNK and the spacer CS, and the height adjustment of the spacer CS.

The bank BNK may be located on (e.g., below) the capping layer CPL. For example, the bank BNK may be located on (e.g., below) the capping layer CPL in the light-blocking area BA. The bank BNK may surround the first patterns PT1 and the second patterns PT2. For example, the bank BNK adjacent to the first patterns PT1 may extend along the first patterns PT1 to be partially located on/below the first patterns PT1 in the first to third transmitting areas TA1, TA2, and TA3. The bank BNK adjacent to the second patterns PT2 may extend along the second patterns PT2 to be partially located on/below the second patterns PT2 in the light-blocking area BA.

The bank BNK may include first openings OP1 partially exposing respective first patterns PT1. Light emitted from the light-emitting elements LD may be incident on the first patterns PT1 through the first openings OP1. The bank BNK may include second openings OP2 partially exposing respective second patterns PT2. At least one spacer CS may be located on (e.g., below) the second patterns PT2 exposed by the second openings OP2.

The bank BNK may reduce or prevent color mixing from occurring due to light introduction between adjacent first to third sub-pixels PXS1, PXS2, and PXS3 (see FIG. 3). The bank BNK may include a material capable of blocking light transmission or reflecting light. For example, the bank BNK may include at least one of an organic/inorganic light-blocking material, a black material, such as a black pigment or a black dye, or a reflective material.

In one or more embodiments, the bank BNK may be made of a non-liquid-repellent material. When the first patterns PT1 and the second patterns PT2 are formed through a photo process, the bank BNK is formed using a low-cost non-liquid repellent material, thereby reducing manufacturing costs. When the first patterns PT1 and the second patterns PT2 are formed by an inkjet process, because the bank BNK is formed using an expensive liquid repellent material to stably spray the ink composition at a desired position, manufacturing costs may increase.

The spacer CS may be located on (e.g., below) the second patterns PT2 in the light-blocking area BA. For example, the spacer CS may be located on (e.g., below) the second patterns PT2 exposed by the second openings OP2 of the bank BNK. FIG. 4 illustrates the spacer CS located on (e.g., below) one of the second patterns PT2, but embodiments are not limited thereto. For example, the spacer CS may be selectively located to overlap each of the second patterns PT2 according to design. The spacer CS may be located on (e.g., below) the second patterns PT2 to contact the encapsulation layer 120.

In one or more embodiments, the spacer CS may include substantially the same material as the bank BNK. The spacer CS may be formed in one process along with the bank BNK. For example, the bank BNK and the spacer CS may be concurrently or substantially simultaneously patterned through exposure and development after applying a photosensitive material. Based on the surface of the second pattern PT2 exposed by the second opening OP2, the spacer CS may be patterned to be thicker than the bank BNK.

The spacer CS may maintain a gap with a structure located on an upper portion thereof. For example, the spacer CS may maintain a cell gap (or distance) between the display substrate 10 and the color filter substrate 30. As a result, because the spacer CS may be located between the second substrate 310 of the color filter substrate 30 and the display substrate 10 to maintain the gap between the two members, a separate design of the viscosity and/or curing degree of the filling layer 20 for maintaining the gap between the display substrate 10 and the color filter substrate 30 may not be required. Accordingly, the manufacturing process time may be shortened, and the design of the filling layer 20 may be facilitated. In addition, because the distance between the display substrate 10 and the color filter substrate 30 may be maintained constant, the thicknesses of various components may be maintained constant compared to the case of adjusting the distance between the display substrate 10 and the color filter substrate 30 depending on the filling layer 20. Accordingly, the occurrence of stains that may occur due to uneven distance between the display substrate 10 and the color filter substrate 30 may be reduced.

As shown in FIG. 4, the color filter substrate 30 may omit a light conversion layer (or wavelength conversion layer) that converts the wavelength of light emitted from the light-emitting elements LD. Accordingly, a light conversion layer (or wavelength conversion layer) may not exist between the color filter substrate 30 and the display substrate 10. For example, a light conversion layer (or wavelength conversion layer) may not exist between the color filter layer CFL and the light-emitting structures EMS.

The filling layer 20 may be located between the display substrate 10 and the color filter substrate 30. For example, the filling layer 20 may be located between the encapsulation layer 120 of the display substrate 10 and the first patterns PT1, second patterns PT2, and bank BNK of the color filter substrate 30. The filling layer 20 may not be located in an area that overlaps the spacer CS, but instead may surround the spacer CS. However, the embodiments are not limited thereto. For example, a capping layer may be located on the first patterns PT1, the second patterns PT2, the bank BNK, and the spacer CS of the color filter substrate 30, and the filling layer 20 may be located between the encapsulation layer 120 of the display substrate 10 and the capping layer. The filling layer 20 may be made of a silicon-based organic material, and an epoxy-based organic material, or the like, but embodiments are not limited thereto.

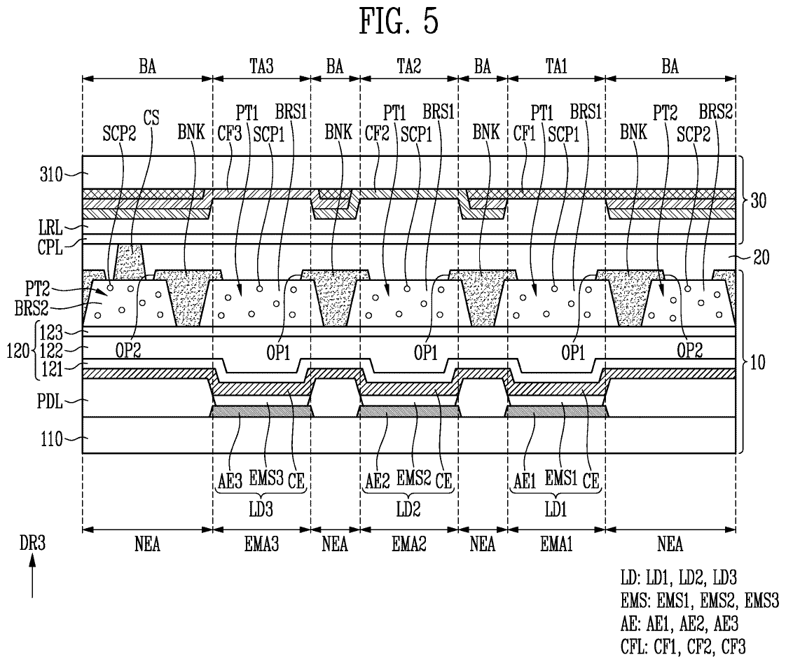

FIG. 5 is a cross-sectional view of a display device in accordance with one or more embodiments. With respect to FIG. 5, descriptions of content overlapping with FIG. 4 are simplified or omitted.

Referring to FIG. 5, the display substrate 10 may include the first substrate 110, and the pixel-defining film PDL, the light-emitting elements LD, the encapsulation layer 120 covering the light-emitting elements LD, the first patterns PT1, the second patterns PT2, the bank BNK, and the spacer CS located on one surface of the first substrate 110. The color filter substrate 30 may include the second substrate 310 facing the first substrate 110, the low-reflective layer LRL located on one side of the second substrate 310, and the capping layer CPL. That is, unlike FIG. 4, the first patterns PT1, the second patterns PT2, the bank BNK, and the spacer CS may be included in the display substrate 10.

The first patterns PT1 may be located on (as used herein, “on” may mean “above”) the encapsulation layer 120. For example, some of the first patterns PT1 may be located on the encapsulation layer 120 in the first transmitting area TA1. For example, some of the first patterns PT1 may be located on the encapsulation layer 120 in the second transmitting area TA2. For example, some of the first patterns PT1 may be located on the encapsulation layer 120 in the third transmitting area TA3. Some of the first patterns PT1 may also be located on the encapsulation layer 120 in the light-blocking area BA. The first patterns PT1 may be spaced apart from each other on the encapsulation layer 120.

The second patterns PT2 may be located on the encapsulation layer 120. For example, the second patterns PT2 may be located on the encapsulation layer 120 in the light-blocking area BA. The second patterns PT2 may be spaced apart from each other on the encapsulation layer 120. The second patterns PT2 may be spaced apart from the first patterns PT1 on the encapsulation layer 120. The second patterns PT2 may be formed in a single process together with the first patterns PT1. For example, the first patterns PT1 and the second patterns PT2 may be concurrently or substantially simultaneously patterned through exposure and development after applying a photosensitive material. The second patterns PT2 may be located on the same layer as first patterns PT1.

The bank BNK may be located on the encapsulation layer 120. For example, the bank BNK may be located on the encapsulation layer 120 in the light-blocking area BA. The bank BNK may surround the first patterns PT1 and the second patterns PT2. For example, the bank BNK adjacent to the first patterns PT1 may extend along the first patterns PT1 to be partially located on the first patterns PT1 in the first to third transmitting areas TA1, TA2, and TA3. The bank BNK adjacent to the second patterns PT2 may extend along the second patterns PT2 to be partially located on the second patterns PT2 in the light-blocking area BA.

The spacer CS may be located on the second patterns PT2 in the light-blocking area BA. For example, the spacer CS may be located on the second patterns PT2 exposed by the second openings OP2 of the bank BNK. FIG. 5 illustrates the spacer CS located on some of the second patterns PT2, but embodiments are not limited thereto. For example, the spacer CS may be selectively located in each of the second patterns PT2 according to design. The spacer CS may be located on the second patterns PT2 to contact the capping layer CPL.

The filling layer 20 may be located between the display substrate 10 and the color filter substrate 30. For example, the filling layer 20 may be located between the first patterns PT1, the second patterns PT2, and the bank BNK of the display substrate 10, and the capping layer CPL of the color filter substrate 30. The filling layer 20 may not be located in an area that overlaps the spacer CS, but may surround the spacer CS.

As shown in FIG. 5, the color filter substrate 30 may omit a light conversion layer (or wavelength conversion layer) that converts the wavelength of light emitted from the light-emitting elements LD. Accordingly, a light conversion layer (or wavelength conversion layer) may not exist between the color filter substrate 30 and the display substrate 10. For example, a light conversion layer (or wavelength conversion layer) may not exist between the color filter layer CFL and the light-emitting structures EMS.

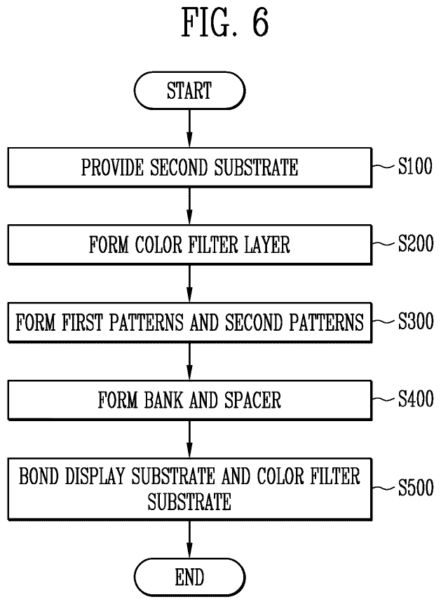

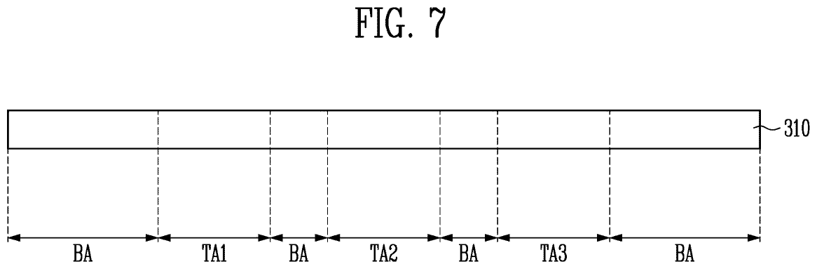

FIG. 6 is a flowchart of a method of manufacturing a display device in accordance with one or more embodiments. FIGS. 7 to 14 are cross-sectional views of process operations of a method of manufacturing a display device in accordance with one or more embodiments. Operations S100, S200, S300, and S400 of FIG. 6, and FIG. 7 to FIG. 13 corresponding thereto, may be a manufacturing method of the color filter substrate 30 shown in FIG. 4.

Referring to FIG. 4 and FIG. 6, the manufacturing method of the display device 1 (see FIG. 1) according to one or more embodiments may include providing the second substrate 310 (S100), forming the color filter layer CFL on the second substrate 310 (S200), forming the first patterns PT1 and the second patterns PT2 on the color filter layer CFL (S300), forming the bank BNK on the first patterns PT1 and the second patterns PT2, and forming the spacer CS on at least one of the second patterns PT2 (S400), and bonding the display substrate 10 and the color filter substrate 30 (S500). Hereinafter, the manufacturing method of the display device 1 will be sequentially described.

First, the second substrate 310 may be provided (S100).

Referring to FIG. 7, the second substrate 310 including the light-transmitting areas TA (see FIG. 3) and the light-blocking area BA may be provided. The second substrate 310 may include the first to third light-transmitting areas TA1, TA2, and TA3 spaced apart from each other, and the light-blocking area BA between the first to third light-transmitting areas TA1, TA2, and TA3. The second substrate 310 may be a base member of the color filter substrate 30.

Next, the color filter layer CFL may be formed (S200).

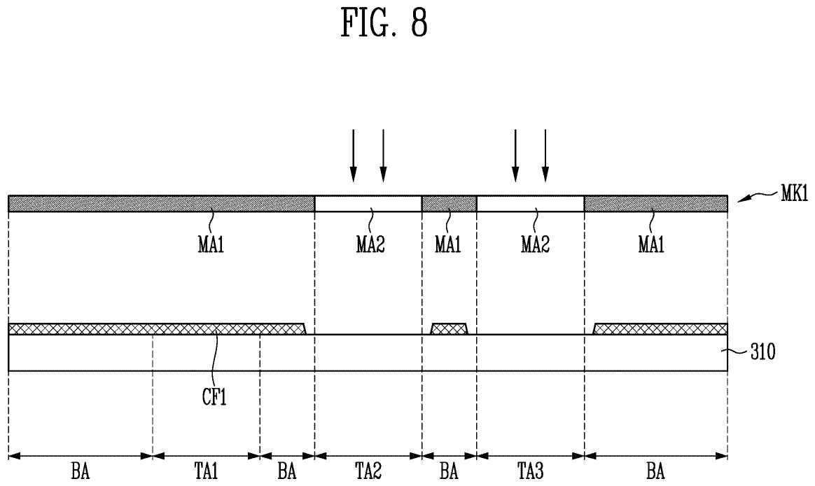

Referring to FIG. 8, the first color filter CF1 may be formed on the second substrate 310. For example, the first color filter CF1 overlapping the first light-transmitting area TA1 and the light-blocking area BA, and non-overlapping the second light-transmitting area TA2 and the third light-transmitting area TA3, may be formed. After applying a first photosensitive material on the second substrate 310, the first photosensitive material may be exposed and developed through a first mask MK1 to pattern the first color filter CF1.

The first photosensitive material may have the first color (for example, blue). A portion of the first photosensitive material overlapping a first area MA1 of the first mask MK1 may remain, and the portion of the first photosensitive material may be developed due to diffraction of light or the like. A portion of the first photosensitive material overlapping a second area MA2 of the first mask MK1 may be developed and removed. In FIG. 8, the first photosensitive material is illustrated as being a positive type, but embodiments are not limited thereto. For example, the first photosensitive material may be a negative type, and the shape of the first mask MK1 may be changed correspondingly.

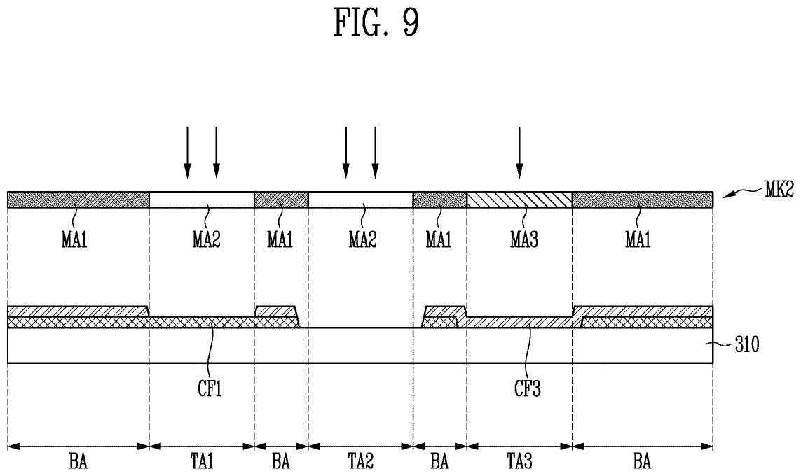

Referring to FIG. 9, the third color filter CF3 may be formed on the second substrate 310 and the first color filter CF1. For example, the third color filter CF3 overlapping the third light-transmitting area TA3 and the light-blocking area BA, and non-overlapping the first light-transmitting area TA1 and the second light-transmitting area TA2, may be formed. After a third photosensitive material is applied on the second substrate 310 and the first color filter CF1, the third photosensitive material is exposed and developed through the second mask MK2 to pattern the third color filter CF3.

The third photosensitive material may have the third color (for example, red). A portion of the third photosensitive material overlapping the first area MA1 of the second mask MK2 may remain, and the portion of the third photosensitive material may be developed due to diffraction of light or the like. A portion of the third photosensitive material overlapping the second area MA2 of the second mask MK2 may be developed and removed. A portion of the third photosensitive material overlapping a third area MA3 of the second mask MK2 may be partially developed and removed. The third area MA3 of the second mask MK2 may have a smaller exposure amount than the second area MA2 thereof, so a portion of the third photosensitive material overlapping the third area MA3 may remain. In FIG. 9, the third photosensitive material is illustrated as being a positive type, but embodiments are not limited thereto. For example, the third photosensitive material may be a negative type, and the shape of the second mask MK2 may be changed correspondingly.

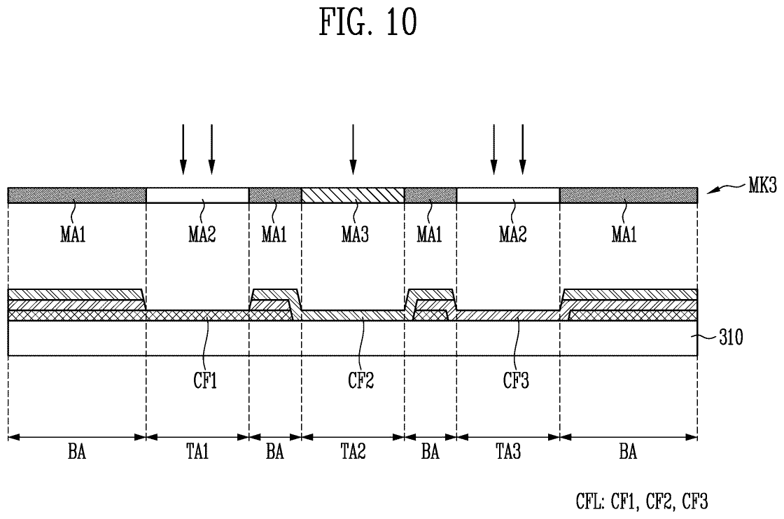

Referring to FIG. 10, the second color filter CF2 may be formed on the second substrate 310, the first color filter CF1, and the third color filter CF3. For example, the second color filter CF2 overlapping the second light-transmitting area TA2 and the light-blocking area BA, and non-overlapping the first light-transmitting area TA1 and the third light-transmitting area TA3, may be formed. After a second photosensitive material is applied on the second substrate 310, on the first color filter CF1, and on the third color filter CF3, the second photosensitive material is exposed and developed through the third mask MK3 to pattern the second color filter CF2.

The second photosensitive material may have the second color (for example, green). A portion of the second photosensitive material overlapping the first area MA1 of the third mask MK3 may remain, and the portion of the second photosensitive material may be developed due to diffraction of light or the like. A portion of the second photosensitive material overlapping the second area MA2 of the third mask MK3 may be developed and removed. A portion of the second photosensitive material overlapping the third area MA3 of the third mask MK3 may be partially developed and removed. The third area MA3 of the third mask MK3 may have a smaller exposure amount than the second area MA2 thereof, so a portion of the second photosensitive material overlapping the third area MA3 may remain. In FIG. 10, the second photosensitive material is illustrated as being a positive type, but embodiments are not limited thereto. For example, the second photosensitive material may be a negative type, and the shape of the third mask MK3 may be changed correspondingly.

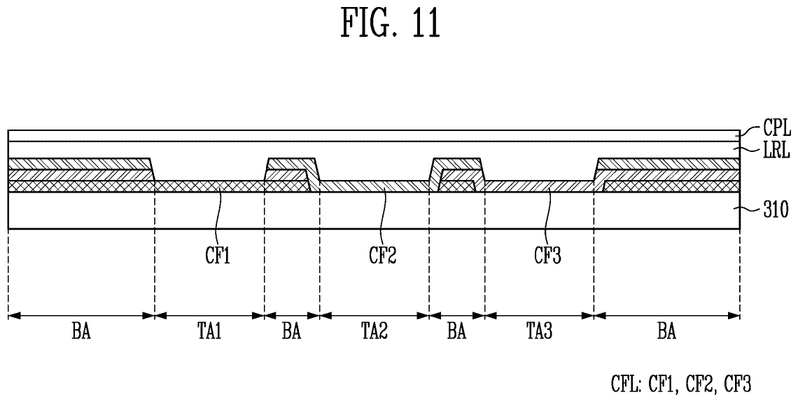

Referring to FIG. 11, the low refractive index layer LRL may be formed on the color filter layer CFL, and the capping layer CPL may be formed on the low refractive index layer LRL, but embodiments are not limited thereto. For example, operations for forming the low refractive index layer LRL and the capping layer CPL may be omitted.

Next, the first patterns PT1 and the second patterns PT2 may be formed (S300).

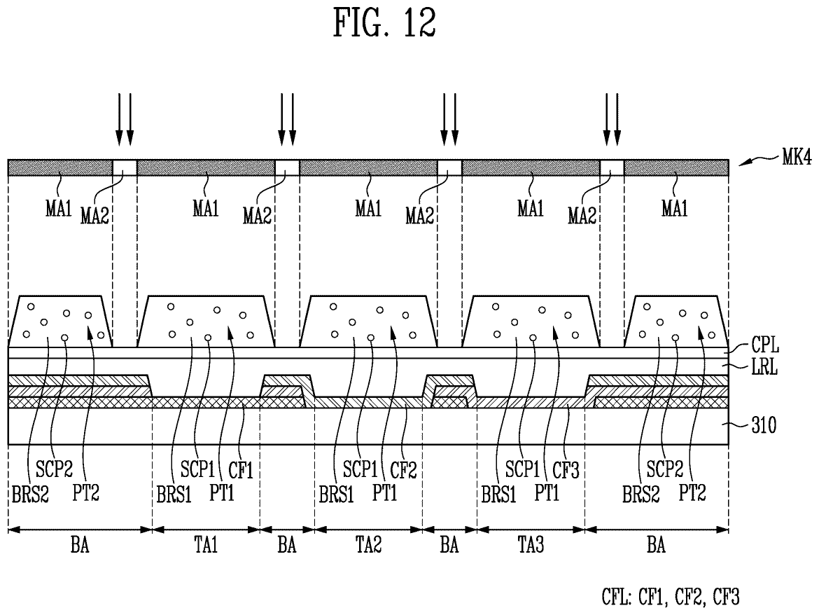

Referring to FIG. 12, the first patterns PT1 and the second patterns PT2 spaced apart from each other may be formed on (e.g., above) the capping layer CPL. For example, the first patterns PT1 overlapping the first color filter CF1 may be formed in the first light-transmitting area TA1 on the capping layer CPL. The first patterns PT1 overlapping the second color filter CF2 may be formed in the second light-transmitting area TA2 on the capping layer CPL. The first patterns PT1 overlapping the third color filter CF3 may be formed in the third light-transmitting area TA3 on the capping layer CPL. The second patterns PT2 overlapping the light-blocking area BA may be formed on the capping layer CPL. After the fourth photosensitive material is applied on the capping layer CPL, the fourth photosensitive material may be exposed and developed through the fourth mask MK4 to pattern the first patterns PT1 and the second patterns PT2. That is, the first patterns PT1 and the second patterns PT2 may be concurrently or substantially simultaneously patterned using one mask.

The fourth photosensitive material includes the first base resin BRS1 and the first scatterers SCP1, and may have the fourth color (for example, white). Alternatively, the fourth photosensitive material includes the second base resin BRS2 and the second scatterers SCP2, and may have the fourth color (for example, white). The second base resin BRS2 may be substantially the same as the first base resin BRS1, and the second scatterers SCP2 may be substantially the same as the first scatterers SCP1. A portion of the fourth photosensitive material overlapping the first area MA1 of the fourth mask MK4 may remain, and the portion of the second photosensitive material may be developed due to diffraction of light or the like. A portion of the fourth photosensitive material overlapping the second area MA2 of the fourth mask MK4 may be developed and removed. In FIG. 12, the fourth photosensitive material is illustrated as being a positive type, but embodiments are not limited thereto. For example, the fourth photosensitive material may be a negative type, and the shape of the fourth mask MK4 may be changed correspondingly.

Next, the bank BNK and the spacer CS may be formed (S400).

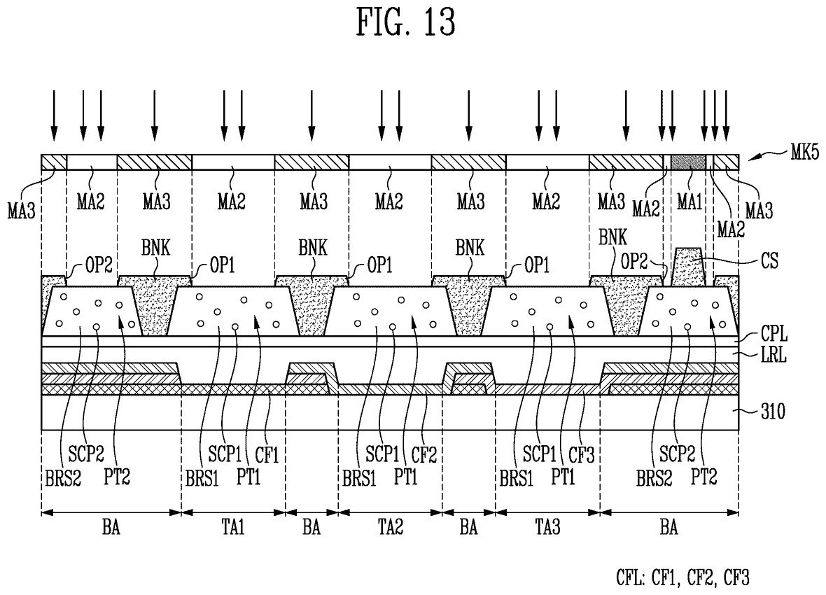

Referring to FIG. 13, the spacer CS may be formed on at least one of the first patterns PT1, the bank BNK surrounding the second patterns PT2, or the second patterns PT2. For example, the bank BNK that extends along the first patterns PT1 to expose a portion of each of the first patterns PT1 may be formed. The bank BNK that extends along the second patterns PT2 to expose a portion of each of the second patterns PT2 may be formed. The spacer CS may be formed on at least one of the exposed portions of the second patterns PT2. After the fifth photosensitive material is applied on the capping layer CPL, the first patterns PT1, and the second patterns PT2, the fifth photosensitive material may be exposed and developed through the fifth mask MK5 to pattern the bank BNK and the spacer CS. That is, the bank BNK and the spacer CS may be concurrently or substantially simultaneously patterned using one mask. Although one spacer CS is illustrated in FIG. 13, embodiments are not limited thereto, and the number of spacers CS may be two or more.

The fifth photosensitive material includes a non-repellent material, and may have a fifth color (for example, black), but embodiments are not limited thereto. For example, the fifth photosensitive material may have various colors, such as red, green, blue, and white. A portion of the fifth photosensitive material overlapping the first area MA1 of the fifth mask MK5 may remain, and the portion of the second photosensitive material may be developed due to diffraction of light or the like. Accordingly, a trapezoidal spacer CS may be formed. A portion of the fifth photosensitive material overlapping the second area MA2 of the fifth mask MK5 may be developed and removed. A portion of the fifth photosensitive material overlapping the third area MA3 of the fifth mask MK5 may be partially developed and removed. The third area MA3 of the fifth mask MK5 may have a smaller exposure amount than the second area MA2 thereof, so a portion of the fifth photosensitive material overlapping the third area MA3 may remain. Accordingly, the first openings OP1 exposing portions of respective first patterns PT1 and the second openings OP2 exposing portions of respective second patterns PT2 may be formed in the bank BNK. In FIG. 13, the fifth photosensitive material is illustrated as being a positive type, but embodiments are not limited thereto. For example, the fifth photosensitive material may be a negative type, and the shape of the fifth mask MK5 may be changed correspondingly.

As such, the color filter substrate 30 (see FIG. 4) may be manufactured using the first to fifth masks MK1, MK2, MK3, MK4, and MK5, that is, five masks.

Next, the display substrate 10 and the color filter substrate 30 may be bonded together (S500).

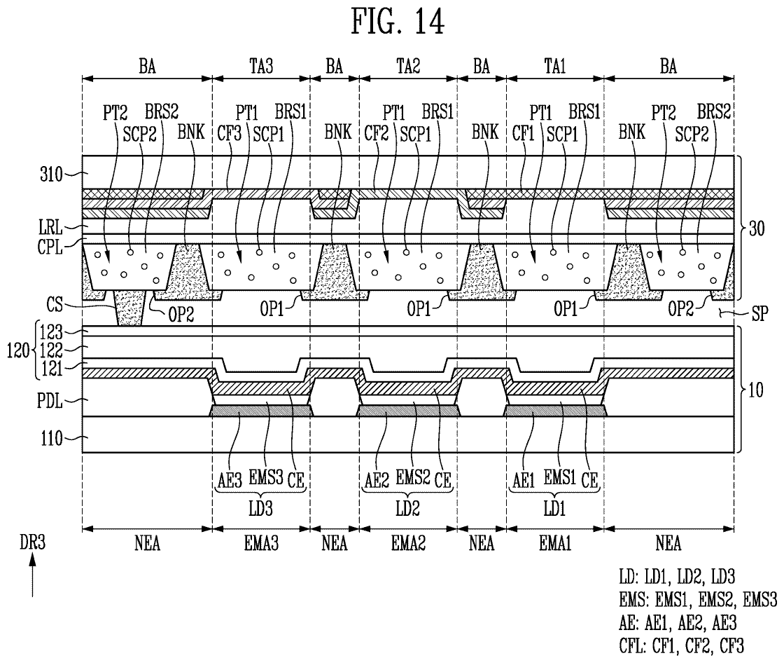

Referring to FIG. 14, the display substrate 10 manufactured through a separate process and the color filter substrate 30 manufactured through operations S100, S200, S300, and S400 may be bonded together. For example, the spacer CS of the color filter substrate 30 may be located on the encapsulation layer 120 of the display substrate 10. An inner space SP is formed between the display substrate 10 and the color filter substrate 30 by the spacer CS. The display substrate 10 and the color filter substrate 30 may be bonded together by forming the filling layer 20 (see FIG. 4) by filling the inner space SP with a filler, such as an organic material.

As described above, because the first patterns PT1 and the second patterns PT2 are formed through the photo process, the manufacturing process may be easily performed. In addition, instead of a partition wall made of an expensive liquid repellent material to form the first patterns PT1, the bank BNK made of a low-cost non-liquid repellent material is formed, and the bank BNK and the spacer CS are formed through one mask, which may reduce the manufacturing cost of the display device 1.

However, aspects of the present disclosure are not limited to those described above, and various other aspects would be understood by one of ordinary skill in the art within the spirit and scope of the present disclosure.

The embodiments described in detail above are provided to explain the present disclosure, but these embodiments are not intended to limit the scope of the present disclosure. It should be understood by those skilled in the art that various changes, substitutions, and alternations may be made therein without departing from the scope of the disclosure as defined by the following claims and their functional equivalents.

The scope of the present disclosure is not limited by detailed descriptions of the present specification and should be defined by the accompanying claims and their equivalents. Furthermore, all changes or modifications of the present disclosure derived from the claims, and equivalents thereof, should be construed as being included in the scope of the present disclosure. The embodiments may be combined to form additional embodiments.

What is claimed is:

1. A display device comprising:
a substrate comprising light-transmitting areas and light-blocking areas;
a color filter layer comprising color filters above the light-transmitting areas;
first patterns below the color filter layer, and overlapping the light-transmitting areas; and
second patterns below the color filter layer, and overlapping the light-blocking area.

2. The display device according to claim 1, wherein the first patterns and the second patterns are at a same layer.

3. The display device according to claim 1, wherein the first patterns and the second patterns comprise a same material.

4. The display device according to claim 3, wherein the first patterns and the second patterns comprise scatterers.

5. The display device according to claim 1, further comprising a bank defining first openings surrounding the first patterns, and respectively exposing portions of the first patterns.

6. The display device according to claim 5, wherein the bank further defines second openings surrounding the second patterns, and respectively exposing portions of the second patterns.

7. The display device according to claim 5, further comprising a spacer overlapping one of the second patterns.

8. The display device according to claim 7, wherein the spacer and the bank comprise a same material.

9. The display device according to claim 8, wherein the spacer and the bank comprise a light-blocking material or a black material.

10. The display device according to claim 8, wherein the spacer and the bank comprise a non-liquid repellent material.

11. The display device according to claim 1, further comprising:
a low refractive index layer overlapping the color filter layer; and
a capping layer overlapping the low refractive index layer.

12. The display device according to claim 1, further comprising a display substrate comprising light-emitting structures,
wherein no light conversion layer exists between the color filter layer and the light-emitting structures.

13. A method of manufacturing a display device, the method comprising:
providing a substrate comprising light-transmitting areas and light-blocking areas;
forming a color filter layer comprising color filters on the light-transmitting areas;
forming first patterns overlapping the light-transmitting areas; and
forming second patterns overlapping the light-blocking area on the color filter layer.

14. The method according to claim 13, wherein the first patterns and the second patterns are formed in one process.

15. The method according to claim 13, wherein the first patterns and the second patterns are made of a same material.

16. The method according to claim 15, wherein the first patterns and the second patterns comprise scatterers.

17. The method according to claim 13, further comprising:
forming a bank on the first patterns and the second patterns; and
forming a spacer on one of the second patterns.

18. The method according to claim 17, wherein the bank and the spacer are formed in one process.

19. The method according to claim 17, wherein the bank defines first openings surrounding the first patterns, and respectively exposing portions of the first patterns, and defines second openings surrounding the second patterns, and respectively exposing portions of the second patterns.

20. The method according to claim 17, wherein the spacer and the bank comprise a same material.

21. The method according to claim 20, wherein the spacer and the bank comprise a light-blocking material or a black material.

22. The method according to claim 20, wherein the spacer and the bank comprise a non-liquid repellent material.

23. The method according to claim 13, further comprising:
forming a low refractive index layer overlapping the color filter layer; and
forming a capping layer overlapping the low refractive index layer.
